(19) United States
(12) Patent Application Publication
(10) Pub. No.: US 2024/0133963 A1
(43) Pub. Date: Apr. 25, 2024

(54) FLOW BATTERY

(71) Applicant: Cambridge Enterprise Limited, Cambridge, Cambridgeshire (GB)

(72) Inventors: Clare Grey, Cambridge, Cambridgeshire (GB); Wenbo Zhao, Cambridge, Cambridgeshire (GB); Edward Shellard, Cambridge, Cambridgeshire (GB)

(21) Appl. No.: 18/278,156

(22) PCT Filed: Feb. 18, 2022
(86) PCT No.: PCT/EP2022/054138

§ 371 Date: Aug. 21, 2023

(30) Foreign Application Priority Data
Feb. 19, 2021 (GB) 2102339.5

(51) Int. Cl. G01R 31/387; G01N 27/76; H01M 8/18

(52) U.S. Cl. CPC G01R 31/387; G01N 27/76; H01M 8/188

(57) ABSTRACT

The invention provides a method for determining the state of charge (SOC) of an electrolyte, such as an electrolyte within a flow battery, by measuring the bulk magnetic susceptibility of the electrolyte. The method includes the step of measuring the magnetic susceptibility of an electrolyte in a measurement region and determining the state of charge of the electrolyte based on the magnetic susceptibility of the electrolyte.

### RELATED APPLICATION

The present case claims priority to, and the benefit of, GB 2102339.5 filed on 19 Feb. 2021, the contents of which are hereby incorporated by reference in their entirety.

### FIELD OF THE INVENTION

The present invention relates to methods and devices for measuring an electrolyte, such as an electrolyte in a (redox) flow battery.

### BACKGROUND

A redox flow battery is a type of electrochemical storage device in which energy is stored in a liquid electrolyte rather than in a solid electrode material. This feature allows the capacity of a redox flow battery to be scaled up in a cost-efficient way simply by changing the size of the electrolyte storage tank. Their layout can also be flexible, as the power generation components and the electrolyte storage tanks can be situated in separate locations. As such, redox flow batteries are a promising technology for large-scale storage applications such as grid-storage.

During battery operation, the electrolytes—known as catholyte and anolyte—flow through an electrochemical cell where they undergo redox reactions, either storing or releasing charge. Two problems may occur when a flow battery is cycled: consumption of the electrolyte by parasitic side-reactions and cross-over of the electrolyte. These problems cause an imbalance in the concentration of the redox-active species in catholyte and anolyte, which results in capacity loss in the battery system.

Typically, the electrolytes can be re-balanced and the capacity restored, allowing the flow battery to operate at full capacity. However, in order to achieve this re-balancing, the state-of-charge (SOC) of each electrolyte, and of the flow battery as a whole, needs to be accurately measured. This amounts to a need to accurately measure the concentration of the redox-active species in the electrolytes at different SOCs.

Open-circuit voltage (OCV) has been used to monitor the SOC of a flow battery (Skyllas-Kazacos et al. 2015). Here, the Nernst Equation can be used to relate the OCV to the ratio of the electrolytes. However, when using the OCV it can be difficult to differentiate between a system that is partially discharged and a system that is unbalanced. Thus, OCV is an unreliable method for determining SOC in a flow battery.

Alternatively, it is possible to measure SOC by placing a reference electrode in each electrolyte storage tank. However, reference electrodes are inherently unreliable, particularly for long-term measurement, as several factors can cause the measured potential to drift over time. Moreover, the solution potential changes are small over a wide range of SOC and so the sensitivity of this method is poor.

The conductivity of the electrolytes has been used as an indicator for SOC. Skyllas-Kazacos et al. demonstrated this method using an all-vanadium flow battery, based on a mechanism in which ion-pairing between SO₄²⁻ and the VO²⁺ and VO₂⁺ caused a shift in acid dissociation equilibria (Skyllas-Kazacos et al. 2011). However, this method is limited to the systems whose ionic conductivity depends on the oxidation state of the electrolytes.

Optical absorption spectroscopy has also been used to monitor the SOC of a flow battery. For example, WO 2016/094436 describes a method for estimating SOC in a flow battery that uses attenuated total reflection spectroscopy. WO 2008/100862 describes a method for estimating SOC using optical absorption spectroscopy. However, although optical methods are applicable to many types of redox couples as the optical properties are inherently coupled to the oxidation state of a molecule, optical methods are still limited by their chemical specificity (Skyllas-Kazacos et al. 2011; Tong et al.).

Accordingly, new approaches for accurately measuring the SOC of a flow battery are needed.

### SUMMARY OF THE INVENTION

The invention generally provides a method for determining the state of charge (SOC) of an electrolyte, such as an electrolyte within a flow battery, by measuring the bulk magnetic susceptibility of the electrolyte, a device for determining the SOC of an electrolyte by measuring the bulk magnetic susceptibility of the electrolyte, and a flow battery comprising the device.

The present inventors have established that the SOC of an electrolyte is proportional to the change in the magnetic susceptibility of the electrolyte. Accordingly, directly measuring the magnetic susceptibility of the electrolyte permits the SOC of the electrolyte, and the SOC of flow battery comprising the electrolyte, to be estimated. The method is applicable to a wide range of redox chemistries, where the magnetic susceptibility of the electrolyte solution changes as a function of concentration of redox-active species within the electrolyte.

Accordingly, in a first aspect of the invention there is provided a method for determining the state of charge of an electrolyte, the method comprising:
(a) flowing an electrolyte through a measurement region;
(b) measuring the magnetic susceptibility of the electrolyte in the measurement region; and
(c) determining the state of charge of the flow battery based on the magnetic susceptibility of the electrolyte.

The inventors have established that magnetic susceptibility of an electrolyte can be accurately and directly measured using a magnetic susceptibility balance.

Accordingly, in a second aspect of the invention, there is provided a measurement device for determining the state of charge of an electrolyte, the device comprising:
(a) a measurement region;
(b) a flow tube configured to permit an electrolyte to pass through the measurement region; and
(c) a detector configured to measure the bulk magnetic susceptibility of the electrolyte in the measurement region,

wherein the detector is a magnetic susceptibility balance.

The magnetic susceptibility balance may be an Evans-type balance.

The magnetic susceptibility balance may be a Gouy-type balance

The device may additionally comprise a data processing unit configured to determine a SOC of an electrolyte based on the magnetic susceptibility of the electrolyte. The device may also comprise a data storage unit for storing the correlation between the magnetic susceptibility of the electrolyte and the SOC of the electrolyte.

The flow tube used in the method and device of the first and second aspects may comprise:
(a) an outer tube, coupled to an outlet at a first end and sealed at a second end; and
(b) an inner tube positioned within the outer tube, the inner tube open at a second end and coupled to an inlet at a first end,

such that the electrolyte must pass from the inlet through the inner tube, into the outer tube and then through the outer tube to the outlet. This configuration permits smooth, uniform flow through the flow tube and reduces any stagnation points where stale electrolyte could accumulate.

The measurement devices of the second aspect may be integrated into a flow battery.

Accordingly, in a third aspect of the invention, there is provided a flow battery comprising the measurement device of the third or fourth aspect.

A typically flow battery system comprises an electrochemical cell, an electrolyte reservoir and a flow circuit configured to permit an electrolyte to circulate between the electrochemical cell and the electrolyte reservoir. In the flow battery of the invention, the measurement device is in fluid communication with the flow circuit. The measurement device may be positioned upstream or downstream of the electrochemical cell.

In a fourth aspect of the invention, there is provided use of the measurement device of the second aspects to determine the state of charge of an electrolyte, a flow battery or a hybrid flow battery.

By determining the SOC of an electrolyte within a flow battery, it is possible to determine the SOC of the whole flow battery. Indeed, the SOC of the flow battery is commonly dependent on the SOC of only one of the electrolytes whose charge capacity is limiting. (That is, the maximum total change capacity of one electrolyte may be smaller than the maximum total charge capacity of the other).

Accordingly, in a fifth aspect of the invention, there is provided a method of determining the SOC of a flow battery, the method comprising:
(a) determining the state of charge of an electrolyte within the flow battery according to the first aspect; and
(b) determining the state of charge of the flow battery based on the state of charge of the electrolyte.

When a flow battery is cycled, the concentration of redox-active species in the electrolytes (e.g. catholyte and anolyte) may become unbalanced. Accordingly, in a sixth aspect of the invention, there is provided a method for rebalancing an electrolyte in a flow battery, the method comprising:
(a) determining the state of charge of an electrolyte within a flow battery on the magnetic susceptibility of the electrolyte according to the method of the first aspect;
(b) determining the quantity of redox-active species within the electrolyte based on the state of charge of the electrolyte;
(c) comparing the quantity of redox-active species to a predetermined reference; and
(d) adjusting the concentration of redox-active species in the electrolyte.

When a flow battery is cycled, additional by-products may arise in the electrolyte. For example, due to cross-over of the electrolyte, consumption of the electrolyte by parasitic side-reactions, or degradation of battery components such as the electrode surface. Accordingly, in a seventh aspect of the invention there is provided a method for detecting cross-over or degradation occurring within a flow battery, the method comprising:
(a) flowing an electrolyte through a measurement region;
(b) measuring the magnetic susceptibility of the electrolyte in the measurement region;
(c) comparing the magnetic susceptibility of the electrolyte to a predetermined reference; and
(d) determining the presence of by-product species within the electrolyte.

These and other aspects and embodiments of the invention are describe in further detail below.

### SUMMARY OF THE FIGURES

The present invention is described with reference to the figures listed below.

FIG. 1 is a schematic of the in situ NMR setup. The battery is set up outside the NMR magnet. The catholyte potassium ferro/ferri cyanide solution is pumped through the NMR probe. On the right, a 10 mm (O.D.) flow NMR tube used as the sampling apparatus in the NMR probe.

FIG. 2 shows in situ ¹H NMR spectra acquired during electrochemical cycling. The voltage and ¹H NMR spectra of the catholyte solution, a 20 cm³ 200 mM K₄[Fe(CN)₆], versus 20 cm³ 300 mM AQ in a full cell comprising of two graphite flow plates with serpentine flow patterns, two 5.0 cm² carbon felt electrodes and a Nafion 212 membrane. The flow rate was set at 13.6 cm³/min. The data was acquired while charging/discharging with a current of 100 mA. The scale indicates the intensity of the resonances in arbitrary units. The NMR signal arises from water, the water comprising a mixture of rapid exchanging H₂O, HDO and D₂O molecules.

FIG. 3 shows in situ ¹H NMR spectra acquired during electrochemical cycling. The voltage, concentration and ¹H NMR spectra of the catholyte obtained from a 20 cm³ 200 mM K₄[Fe(CN)₆] versus 20 cm³ 300 mM AQ full cell, acquired while charging/discharging with a current of 100 mA. The scale indicates the intensity of the resonances in arbitrary units. The NMR signal arises from resonances of water molecules which are existing in the form of H₂O, HDO or D₂O.

FIG. 4 shows bulk magnetic susceptibility and concentrations of ferricyanide ions. In 4a, the voltage of a 20 cm³ 200 mM K₄[Fe(CN)₆] vs 20 cm³ 300 mM AQ full cell is shown at the top; in the middle, the susceptibility as a function of time during electrochemical cycling; at the bottom, the concentration of Fe(III)(CN)₆³⁻ anions as a function of time, calculated assuming a μ_{eff} value of 2.14. 4b shows susceptibility as a function of battery capacity. The blue squares represent the experimental data, the central (red) line represents the fit using Equation 6. The lines are coincident at the scale shown. A slope of 0.0036 ppm mA⁻¹hr¹ was obtained with a R²=1.00.

FIG. 5 shows bulk magnetization measurements performed using an Evans-type magnetic susceptibility balance. 5a shows the flow sampling apparatus designed for the balance. A 1/16″ PFA tube is used as the inlet and inserted to the bottom of a 3 mm O.D. glass tube. The side arm on the right is the outlet. The apparatus is placed in the balance at a depth of 50 mm. In 5b, the voltage of a 15 cm³ 570 mM K₄[Fe(CN)₆] versus 20 cm³ 300 mM AQ full cell is shown at the top; at the bottom, the changes of readings from the Evans balance and the concentration of K₃[Fe(CN)₆] (right-axis) during electrochemical cycling. Measurements were taken every five minutes and error bars show the variance of the five readings at 10 second intervals which were averaged. The solid (blue) line represents the best fit to the data points.

FIG. 6 shows the flow sampling apparatus designed for the Evans balance. A 1/16″ PFA tube is used as the inlet and inserted to the bottom of a 3 mm O.D. glass tube. The side arm on the right is the outlet. The white connectors are ⅛″ to ¼″ Swagelok connectors made of TEFLON. A short piece of ⅛″ PFA tube is connected to this connector and another ⅛″ to 1/16″ Swagelok connector (bored-through) at the top. The 1/16″ PFA tube passes through these connectors and the ⅛″ tube to the bottom of the glass tube. The inset on the right shows the 1/16″ PFA tube inside the glass tube.

FIG. 7 shows pictures of a balance configuration. FIG. 7a shows an electrolyte reservoir held between two neodymium magnets positioned on a sensitive laboratory weighing balance. FIG. 7b shows the electrolyte reservoir and electrolyte in more detail, between two neodymium magnets. The magnets are placed on top of and act on the balance, so that the balance measures the force acting on the magnets. The electrolyte reservoir and electrolyte contained therein are suspended from a clamp stand, and so do not directly place weight on the weighing balance.

FIG. 8 shows a graph of concentration of K₃[Fe(III)(CN)₆] solution against a relative weight of the magnets. The different electrolyte concentrations have different magnetic susceptibilities and so result in a different force acting on the magnets. The data was measured using the balance shown in FIG. 7 and described in Example 3.1.

FIG. 9 shows a picture of a balance configuration using electromagnets. FIG. 9a shows an electrolyte reservoir suspended between the electromagnets. FIG. 9b shows a more detailed view of a counter balance configuration, used in order to keep the overall weight below the laboratory balance's maximum limit. The electromagnets act on the weighing balance via the counter balance configuration. The electrolyte reservoir and electrolyte are suspended from a clamp stand, and are not directly acting on the weighing balance. In FIG. 9a the counterbalance has been removed for clarity and the electromagnets are represented with washers.

### DETAILED DESCRIPTION OF THE INVENTION

The invention generally provides a method for determining the state of charge (SOC) of an electrolyte, such as an electrolyte within a (redox) flow battery, by measuring the bulk magnetic susceptibility of the electrolyte, a device for determining the SOC of an electrolyte by measuring the bulk magnetic susceptibility of the electrolyte, and a flow battery comprising the device.

Zhao et al. have previously described in-situ NMR methods for studying redox flow batteries. In the method of Zhao et al., the ¹H NMR shift of the water resonance in the aqueous electrolyte is monitored as it flows out of the electrochemical cell. The authors ascribe the shift in the water solvent resonance to bulk magnetic susceptibility (BMS) effects. The concentration of radical (or, more generally, magnetic) species can be estimated from this shift in bulk magnetic susceptibility using the method described by Evans et al., and this can provide an estimate of the SOC of the flow battery.

The method of Zhao et al. measures the ¹H NMR resonance of water in the electrolyte, and this provides only an indirect measure of bulk magnetic susceptibility. The method of Zhao et al. requires the use of a complex NMR apparatus, including in one experimental set-up strong, superconducting electromagnets, which must be kept at low temperatures. This leads to extremely high measurement costs. In addition, the method of Zhao et al. relies on observing the water resonance to determine state of charge. As such, it has only been applied to aqueous electrolyte systems.

WO 2010/091170 has previously described a method and device for measuring the state of charge of a battery. The device uses a permanent magnet or an electromagnet to generate a magnetic field that permeates the battery. The device then uses a magnetic field sensor (e.g. a fluxgate) to detect changes in the magnetic properties of the object, such as the magnetic susceptibility of the object (see paragraph [0041]).

However, WO 2010/091170 relates to traditional batteries, rather than redox flow batteries used in the present invention. The single example in WO 2010/091170 uses a lithium-iron-phosphate battery. As such, the device of WO 2010/091170 does not isolate the electrolyte from the battery for measurement. The present invention uses a flow tube to allow an electrolyte to flow through the measurement device, which is possible for a flow battery but not a traditional battery.

The device of WO 2010/091170 also measures the magnetic susceptibility of the battery by measuring changes in the magnetic field applied to the battery. In contrast, the present invention measures the magnetic susceptibility by measuring the force applied to the magnets (e.g. in a Evans balance) or the force applied to a sample of electrolyte (e.g. in an Gouy balance). In each case, the electrolyte is isolated from the flow battery for the measurement of magnetic susceptibility.

EP 2535730 also previously describes a method and device for measuring the “state of health” and the state of charge of a battery. The device uses a permanent magnet to apply a magnetic field to permeate the battery, and then uses a magnetic field sensor to detect the resultant magnetic field, which is said to be proportional to the magnetic susceptibility of the battery (see paragraphs [0046], [0049] and [0050]). EP 2535730 is solely concerned with traditional batteries (paragraphs[0038] and [0041]) and not flow batteries as for the present invention. EP 2535730 also does not describe a flow tube including electrolyte isolated from a flow battery, and does not measure the force applied to the magnets or the isolated electrolyte (e.g. as in the example Gouy or Evans balance configurations described for the present invention).

### Electrolyte

The SOC of an electrolyte depends on the relative amounts of the redox-active species present in the electrolyte, for example, to the relative amounts of reduced and oxidised species present in the electrolyte. The present method is applicable to any electrolyte system in which the magnetic susceptibility of the electrolyte changes as a function of the concentration of redox-active species within the electrolyte. That is, any electrolyte system in which the different redox-active species in the electrolyte have different magnetic susceptibilities. As the redox reactions that occur during charging and discharging of the electrolyte involve the transfer of electrons, at least some of the redox-active species in the electrolyte are typically paramagnetic, and typically include radical or ionic species comprising unpaired electrons. Thus, the magnetic susceptibility of the electrolyte will change depending on the concentration of these species. Indeed, this requirement is generally fulfilled by many electrolyte systems used in flow batteries.

Accordingly, the magnetic susceptibility of the electrolyte changes as a function of the state of charge of the electrolyte. In some embodiments, the electrolyte has a different magnetic susceptibility in its charged and uncharged forms.

In some embodiments, the electrolyte comprises a redox-active species having a reduced and an oxidised form. Typically, the reduced and oxidised forms have different magnetic susceptibilities. That is, the magnetic susceptibility of the reduced and oxidised forms differ.

Optionally, the electrolyte may additionally comprise a redox-active species having one or more intermediate forms. Typically, at least one of the reduced, oxidised and intermediate forms has a different magnetic susceptibility to the remaining forms.

In some embodiments, the electrolyte comprises a paramagnetic redox-active species. Typically, at least one of the reduced, oxidised or intermediate forms of the redox-active species is paramagnetic. The paramagnetic redox active species may be present in the electrolyte when the electrolyte is in its uncharged or charged state, or may be present in an intermediate state.

Electrolytes for use in flow batteries may be classified based on the type of redox-active species present in the electrolyte. Suitable electrolyte systems for use in a flow battery of the invention include metal-based systems, organic-molecule based systems and polymer-based systems and combinations of these.

Suitable metal-based electrolyte systems include those based on iron, vanadium, chromium, manganese, zinc and organic molecule-based systems that involve radical anions and cations.

Suitable iron-based systems include those based on an Fe(II) and F(III) species. Examples of iron-based electrolyte species include K₄[Fe(CN)₆], Fe(C₅H₅)₂, FeCl₃ and FeCl₂.

Suitable vanadium-based systems include those based on V(V), V(IV), V(III) and V(II). Example vanadium-based electrolytes species include VO₂(H₂O)₄⁺ and V(H₂O)₆³⁺.

Suitable chromium-based systems include those based on Cr(III) and Cr(II) species. Example chromium-based electrolyte species include CrCl₃ and CrCl₂.

Specific examples of flow batteries (RBF) and hybrid flow batteries (HFB) comprising suitable inorganic electrolyte systems include the vanadium redox flow battery (VRFB), the Fe/Cr RFB, the Zn/Ce RFB and the Fe/S RFB.

Suitable organic-molecule-based electrolyte systems include those based on quinone (Q), anthraquinone (AQ), 2,2,6,6-tetramethylpiperidine-1-oxyl (TEMPO), flavin, alkoxybenzene, azobenzene and others.

Example quinone-based electrolyte species include para-benzoquinone (chloranil, QCl₄), 4,5-dibenzoquinone-1,3-benzenedisulfonate (trion), 1,2-benzoquinone-3,5-disulfonic acid (BQDS),

Example anthraquinone-based electrolyte species include 2,6-dihydroxyanthraquinone (2,6-DHAQ), anthraquinone-2-sulfonic acid (AQS), anthraquinone-2,6-disulfonic acid, 9,10-anthraquinone-2,7-disulfonic acid (AQDS), 3,4-dihydroxy-9,10-anthraquinone-2-sulfonic acid (ARS), 4,4-((9,10-anthraquinone-2,6-diyl)dioxy)dibutyrate (DBEAQ), anthraquinones with methoxytriethyleneglycol substituents such as 15D3GAQ, diaminoanthraquinones (DAAQs) such as Disperse Blue 134 (DB-134),

Example TEMPO-based electrolyte species include TEMPO, 4-hydroxy-2,2,6,6-tetramethylpiperidine-1-oxyl (4-HOTEMPO) and 4-methoxy-2,2,6,6-tetramethylpiperidine-1-oxyl (MeO-TEMPO).

Example alkoxybenzene-based electrolyte species include 2,5-di-tert-butyl-1,4-bis(2-methoxyethoxy)benzene (DBBB), ANL-8, ANL-9, ANL-10, 2,3-dimethyl-1,4-dimethoxybenzene (23DDB) and 2,5-dimethyl-1,4-dimethoxybenzene (25DDB).

Further examples of organic-molecule based electrolyte species include nitronyl nitroxide radical-based systems such as 2-phenyl-4,4,5,5-tetramethylimidazoline-1-oxyl oxide (PTIO) 2,3,6-trimethylquinoxaline (TMeQ), viologens such as methyl viologen (MV), 3,7-bis(trifluoromethyl)-N-ethylphenothiazine (BCF3EPT), 9-fluorenone (FL) and alloxazine.

Example flavin-based electrolyte systems include riboflavin, flavin mononucleotide and flavin adenine dinucleotide.

Example azo compound-based electrolyte systems include azobenzene, 4-methoxyazo-benzene and 4-hydroxyazobenzene.

Suitable polymer-based electrolyte systems include those based on polythiophene (PT), polyanalines (PANI), poly(vinylbenzylethylviologens), TEMPO-based polymers and poly(boron dipyrromethenes) (BODIPYs).

Example TEMPO-based polymers include bottlebrush polymers such as poly(norbornene)-g-poly(4-methacryloyloxy-2,2,6,6-tetramethylpiperidine-1-oxyl) (PNB-g-PTMA) and block copolymers polymers such as P(TMA-co-METAC) and P(TMA-co-PEGMA), where TMA is TEMPO methacrylate, METAC is [2-(methacryloyloxy)ethyl]trimethylammonium chloride, and PEGMA is poly-(ethylene glycol) methacrylate).

The electrolyte typically contains a solvent. The solvent may be aqueous or organic as appropriate.

Example organic solvents include ethylene carbonate.

Typically, the solvent is aqueous (water).

The aqueous solvent may contain additional dissolved ions to improve conductivity. The additional dissolved ions may be known as supporting electrolyte ions. Typical dissolved ions include KOH, NaOH, KCl and NaCl.

### Flow Tube

The measurement device of the invention comprises a flow tube configured to permit an electrolyte to pass through a measurement region.

The flow tube comprises an inlet and an outlet to permit entry and exist of electrolyte.

Preferably, the flow tube has a “tube-in-a-tube” configuration. In such cases, the flow tube comprises an inner tube positioned within an outer tube. The inner and outer tube are in fluid communication toward one end. Typically, the flow tube comprises (a) an outer tube, coupled to an outlet at a first (e.g. top) end and sealed at a second (e.g. bottom) end; and (b) an inner tube positioned within the outer tube, the inner tube coupled to an inlet at a first (e.g. top) end and open at a second (e.g. bottom) end. In this configuration, the electrolyte passes from the inlet into the inner tube at a first end, through the inner tube to the second end, into the outer tube at the second end and then through the outer tube to the outlet at a first end. Typically, the electrolyte must pass through a substantial portion of the length of the inner and outer tube.

This design is preferred because it permits smooth, uniform flow through the flow tube and reduces any stagnation points where stale electrolyte could accumulate. This ensures reliable measurement.

Any suitable material may be used to prepare the flow tube. Suitable materials include metals such as stainless steel, polymers such as perfluoroalkoxy alkanes (PFA) and glass.

### Measurement Region

The measuring device of the invention comprises a measurement region in which measurement of the electrolyte takes place.

The measurement device comprises a detector configured to measure the bulk magnetic susceptibility of the electrolyte in the measurement region.

Preferably, the detector is a magnetic susceptibility balance.

Any magnetic susceptibility balance can be used to measure the magnetic susceptibility of the electrolyte in the measurement region. Example magnetic susceptibility balances include the Evans balance, the Gouy balance and the Faraday balance.

Suitable magnetic susceptibility balances include those manufactured by Johnson Matthey, such as the Johnson Matthey Mark I or Mark II (Auto) Magnetic Susceptibility Balance, and those manufactured by Sherwood Scientific Ltd (UK), such as the Mk I and the Auto.

A magnetic susceptibility balance may determine the magnetic susceptibility of a sample by measuring the force exerted between the sample and a nearby magnet. Accordingly, in some embodiments, the measurement device comprises a first pair of magnets configured to establish a magnetic field across the measurement region. The magnets may be permanent magnets or electromagnets. Preferably the magnets are permanent magnets for ease of construction.

The first pair of magnets may generate a magnetic field of a known (predetermined) field strength. Typically, the magnets are configured to generate a static magnetic field. Typically, the magnets are configured to generate a uniform (homogenous) magnetic field. Providing a pair of magnets enables the generation of a uniform (homogenous) magnetic field.

When a paramagnetic or diamagnetic sample, such as the electrolyte, is placed in the measurement region, the sample interacts with the magnetic field and a force is exerted between the sample and the first pair of magnets. The force is proportional to the magnetic susceptibility of the electrolyte.

Preferably, the magnetic susceptibility balance is an Evans-type balance. The Evans-type balance measures the force exerted on the magnets when a paramagnetic or diamagnetic sample (e.g. the electrolyte) is placed in the measurement region. The force exerted on the magnets is proportional to the magnetic susceptibility of the electrolyte.

Accordingly, the measurement device may comprise a sensor configured to measure the force exerted on the first pair of magnets when the electrolyte is present in the measurement region. Suitable sensors include a force transducer. An Evan balance may use an analytical balance or weighing system to measure the force exerted on the magnets.

In some embodiments, the first pair of magnets is positioned at a first end of a balance arm or beam. The beam is pilotable, typically about the centre of the beam. A torsion balance set up is preferred. Typically, the Evans balance uses a counterweighted or torsion balance set up to measure the force exerted on the magnets.

Typically, the first end of the beam comprises a recess to accommodate the measurement region (e.g., a Y-shaped beam). One magnet of the first pair of magnets is positioned to either side of the recess, to establish a magnetic field across the measurement region. Preferably, the beam is counterweighted to counterbalance the weight of the first pair of magnets.

In the absence of a sample in the measurement region, the beam lies in a rest (e.g. equilibrium) position. When a paramagnetic or diamagnetic sample, such as the electrolyte, is placed in the measurement region, the sample interacts with the magnetic field and exerts a force on the first pair of magnets. This causes displacement of the beam.

The sensor may be configured to measure the force exerted on the beam. In some embodiments, the sensor may measure the displacement of the beam.

In one embodiment, the measurement device may comprise:
(a) second pair of magnets positioned at the second end of the beam and configured to establish a second magnetic field; and
(b) a compensating electromagnet configured to generate a compensating magnetic field to interact with the second magnetic field.

The second pair of magnets may act as a counterbalance to the first pair of magnets. The second pair of magnets may be permanent magnets or electromagnets. Typically, they are permanent magnets for ease of construction. The second pair of magnets may generate a magnetic field of a known (predetermined) field strength. Typically, they are configured to generate a static magnetic field. Typically, they are configured to generate a uniform (homogenous) magnetic field.

In one embodiment, the second end of the beam comprises a recess to accommodate the compensating electromagnet (e.g., an H-shaped beam). One magnet of the second pair of magnets is positioned to either side of the recess, to establish a magnetic field across the recess to interact with the compensating electromagnet.

The compensating electromagnet is configured to generate a compensating magnetic field to interact with the second magnetic field. The magnetic field strength generated by the compensating electromagnet may be varied, for example, by varying the current supplied to the compensating electromagnet. The measurement device may comprise a current controller configured to vary the current supplied to the compensating electromagnet.

When a paramagnetic or diamagnetic sample, such as the electrolyte, is placed in the measurement region, the sample interacts with the magnetic field and exerts a force on the first pair of magnets and causes displacement of the beam. The current supplied to the compensating electromagnet may be adjusted to vary the magnetic field strength of the compensating magnetic field to counteract the displacement of the beam. When the beam returns to the rest (i.e. equilibrium) position, the current supplied to the compensating electromagnet is proportional to the force exerted by the sample (e.g. on the first pair of magnets). In such cases, the sensor may be configured to measure the current supplied to the compensating electromagnet.

The compensating electromagnet may contain a magnetic core, or it may be a solenoid.

The measurement device may include a second sensor configured to determine whether the beam is in the rest (e.g. equilibrium) position. Suitable sensors include optical sensors such as phototransistors.

In one embodiment, the magnetic susceptibility balance is Gouy-type balance. The Gouy-type balance measures the force exerted on the sample when a paramagnetic or diamagnetic sample (e.g. the electrolyte) is placed in the measurement region. The force exerted on the sample is proportional to the magnetic susceptibility of the electrolyte.

Accordingly, the measurement device may comprise a sensor configured to measure the force exerted on the electrolyte when it is present in the measurement region. For example, where the measurement device comprises a flow tube configured to permit an electrolyte to pass through a measurement region, the sensor is configured to measure the force exerted on the flow tube. Suitable sensors include a force transducer. Typically, a Gouy-type balance uses an analytical balance or weighing system to measure the force exerted on the sample.

In some embodiments, the flow tube is positioned at a first end of a balance arm or beam. The beam is pilotable, typically about the centre of the beam. A torsion balance set up is preferred.

In the absence of a sample in the measurement region, the beam lies in a rest (e.g. equilibrium) position. When a paramagnetic or diamagnetic sample, such as the electrolyte, is placed in the measurement region, the sample interacts with the magnetic field and exerts a force on the flow tube. This causes displacement of the beam.

The sensor may be configured to measure displacement of the beam, as set out for the Evans-type system. Similarly, a system comprising a second pair of magnets, a compensating electromagnet and a current controller may also be used to measure the force exerted on the flow tube. The second pair of magnets may counterbalance the flow tube.

In one embodiment, the detector is a magnetic sensor configured to measure the bulk magnetic susceptibility of the electrolyte in the measurement region.

Sensors that measure magnetic fields have previously been incorporated into battery systems, such as flow battery systems, for the purpose of assessing SOC. However, these magnetic sensors are typically used for “coulomb counting”. That is, they are configured to assess the current flowing into or out of the battery over a given time period. This information is used to assess the SOC of the battery against the theoretical capacity of the battery. This provides an indirect measure of the SOC of the battery. The accuracy of coulomb counting methods is typically quite poor and the method suffers from long-term drift, for example because the true capacity of the battery may change with time. As such, the method requires regular re-calibration to maintain accuracy. Environmental factors, such as temperature, may also need to be taken into account.

In the present invention, the magnetic sensor is configured to measure the bulk magnetic susceptibility of the electrolyte. This provides a direct measure of the SOC of the electrolyte, and of a flow battery comprising the electrolyte. This avoids or mitigates many of the problems associated with charge counting.

In one embodiment, the magnetic sensor includes a Hall Effect sensor, a fluxgate, a magnetoresistive device or a superconducting quantum interference device (SQUIDs).

Optionally, the measurement device comprises magnetic shielding. Magnetic shielding reduces the impact of external magnetic fields on the measurement apparatus, increasing sensitivity. The magnetic shielding may be active or passive.

### Data Processing

The measurement device of the invention may comprise a data processing unit configured to determine a state of charge (SOC) of the electrolyte, and an SOC of a flow battery as a whole, based on the output of the detector.

As noted above, the magnetic susceptibility of the electrolyte may be proportional to the SOC of the electrolyte. Accordingly, the data processing unit may calculate the SOC of an electrolyte based on the magnetic susceptibility of the electrolyte.

By determining the SOC of an electrolyte within a flow battery, it is possible to determine the SOC of the whole flow battery. Accordingly, in one embodiment, the data processing unit may be additionally configured to determine the SOC of a flow battery based on the SOC of the electrolyte, or to determine the SOC of a flow battery based on the magnetic susceptibility of the electrolyte.

The SOC of the flow battery as a whole may be determined based on the SOC of each electrolyte individually. However, the SOC of a flow battery is typically dependent on the SOC of only one of the electrolytes whose charge capacity is limiting. (That is, the maximum total charge capacity of one electrolyte may be smaller than the maximum total charge capacity of the other).

The correlation between the SOC of the electrolyte and the magnetic susceptibility of the electrolyte may be known, or it may be determined as set out below.

The correlation between the magnetic susceptibility of the electrolyte and the SOC of the electrolyte may be linear. The linear correlation may be positive of negative. This situation occurs, for example, where the electrolyte has a larger magnetic susceptibility in a charged state in comparison to an uncharged state (or vice versa). Here, the redox-active species in the charged state has a larger magnetic susceptibility than the redox-active species in the discharged state. In the examples, the correlation between the SOC of the electrolyte and the magnetic susceptibility of the electrolyte is a positive linear correlation. A negative linear correlation occurs, for example, in a VRFB where the charging reaction involves oxidation of V⁴⁺ (S=1/2) to V⁵⁺ (S=0) on one side and reduction of V³⁺ (S=1) to V²⁺ (S=3/2).

Alternatively, the correlation between the magnetic susceptibility of the electrolyte and the SOC of the electrolyte may be non-linear (e.g. polynomial). This situation occurs, for example, where the electrolyte has a larger magnetic susceptibility in an intermediate state than in either a charged or uncharged state. This may be the case, for example, where anthraquinonoid-based electrolytes are used. Here, the maximum concentration of the paramagnetic intermediate species (i.e. the radical species) may occur when the electrolyte is charged to approximately 50% of its total capacity.

As noted above, the magnetic susceptibility of the electrolyte may be proportional to the force exerted on the first pair of magnets. Accordingly, in some embodiments, the data processing unit may calculate the SOC of an electrolyte, and optionally the magnetic susceptibility of the electrolyte, based on the force exerted on the first pair of magnets. The correlation between the force exerted on the first pair of magnets, the magnetic susceptibility and the SOC may be known, or it may be determined as set out below.

Similarly, the force exerted on the first pair of magnets may be proportional to the current supplied to the compensating electromagnet. Accordingly, in some embodiments, the data processing unit may calculate the SOC of an electrolyte, and optionally the magnetic susceptibility of the electrolyte, based on the current supplied to the compensating electromagnet. The correlation between the current supplied to the compensating electromagnet, the magnetic susceptibility and the SOC may be known, or it may be determined as set out below.

As noted above, the magnetic susceptibility of the electrolyte may be proportional to the force exerted on the electrolyte when it is present in the measurement region, such as with the flow tube. Accordingly, in some embodiments, the data processing unit may calculate the SOC of an electrolyte, and optionally the magnetic susceptibility of the electrolyte, based on the force exerted on the flow tube. The correlation between the force exerted on the flow tube, the magnetic susceptibility and the SOC may be known, or it may be determined as set out below.

The measurement device may comprise a data storage device for storing the data required for calculating the SOC of the electrolyte. The data storage device may store the correlation between the magnetic susceptibility of one of more known electrolytes and the SOC of the electrolytes. The data storage device may store the expected maximum and minimum magnetic susceptibilities of the electrolyte. The data storage device may store magnetic susceptibilities of the electrolyte in fully charged or fully discharged form, or in fully reduced or fully oxidised form.

In some embodiments, the data storage device may store the correlation between the force exerted on the first pair of magnets, the magnetic susceptibility and the SOC of the electrolyte. In some embodiments, the data storage device may store the correlation between the current supplied to the compensating electromagnet, the magnetic susceptibility and the SOC of the electrolyte. In some embodiments, the data storage device may store the correlation between the force exerted on the flow tube, the magnetic susceptibility and the SOC of the electrolyte.

As noted above, it is possible to determine the SOC of a flow battery by determining the SOC of one or more electrolytes within the flow battery. Accordingly, in some embodiments, the data storage device may store the correlation between the magnetic susceptibility of one of more known electrolytes and the SOC of a flow battery comprising those electrolytes. In some embodiments, the data storage device may store the correlation between the force exerted on the first pair of magnets and the SOC of the flow battery. In some embodiments, the data storage device may store the correlation between the current supplied to the compensating electromagnet and the SOC of the flow battery. In some embodiments, the data storage device may store the correlation between the force exerted on the flow tube and the SOC of the flow battery.

### Flow Battery

The present invention also provides a flow battery or hybrid flow battery comprising the measurement device of the invention.

The flow battery of the invention may comprise an electrochemical cell, an electrolyte reservoir and a flow circuit configured to permit an electrolyte to circulate between the electrochemical cell and the electrolyte reservoir. Redox reactions occur within the electrochemical cell, storing or releasing charge.

The measurement device is in fluid communication with the flow circuit. The measurement device may be positioned upstream or downstream of the electrochemical cell.

The measurement device may be positioned in-line with the flow circuit. In such cases, all the electrolyte passing though the flow circuit also passes through the measurement device.

In an alternative embodiment, the measurement device may be positioned parallel to the flow circuit and a portion of the electrolyte passing through the flow circuit may be diverted into the measurement device. The diverted portion of electrolyte may be returned to the flow circuit after passing through the measurement device. This configuration is particularly suitable for large-scale applications, as the bulk of flow through the flow circuit need not be impeded by passing through the measurement device.

Optionally, the flow battery may comprise a pump for circulating the electrolyte between the electrochemical cell and the electrolyte reservoir. The type of pump is not particularly limited. A piston, peristaltic or rotary pump may be used.

In one embodiment, the flow battery may comprise two electrolytes, known as the catholyte and the anolyte, respectively. In such cases, the flow battery may comprise an anolyte reservoir, a catholyte reservoir, an anolyte flow circuit configured to permit the anolyte to circulate between the electrochemical cell and the anolyte reservoir, and a catholyte flow circuit configured to permit the catholyte to circulate between the electrochemical cell and the catholyte reservoir. A measurement device may be in communication with either the analyte or the catholyte flow circuit. As noted above, a measurement device may be positioned in-line or parallel to either flow circuit.

In such cases, the anolyte and catholyte typically flow across opposing sides of a membrane or separator in the electrochemical cell. The two sides of the cell may be termed the analyte-side and catholyte-side, respectively.

The membrane or separator permits the exchange of ions between the analyte and catholyte side of the electrochemical cell. The membrane or separator may be an ionically conducive polymer.

Preferably, the membrane or separator is selective for the supporting electrolyte ions over the redox-active species present in the electrolytes. This reduces cross-over of the redox-active electrolyte species and reduced capacity of the flow battery.

Typical membrane or separator materials include fluorinated or perfluorinated polymers. Separators such as dialysis membranes, microporous hydrocarbon polymers, polymers of intrinsic microporosity (PIMs) and polyaromatic ionomers having pendant ionic functional groups may be used as appropriate, in particular where solvated polymeric species or particles are utilised as the redox-active species. Ceramic membranes, such as those that are conductive to a single ion, may also be used.

Examples of suitable fluorinate or perfluorinated polymers include sulfonated tetrafluoroethylene copolymers such as Nafion (Dupont), for example Nafion 115, 117 and 212. Examples of dialysis membranes include cellulose-based dialysis membranes. Examples of microporous hydrocarbon polymers include microporous polypropylene or polyethylene. Examples of PIMs include PIMs based on Tröger's base and PIMs based on dibenzodioxin, such as those comprising amidoxime groups.

Alternatively, membrane-free flow batteries are known. In a typical membrane-free flow battery, the catholyte and anolyte solutions pass through the electrochemical cell with little to know mixing. This may be achieved, for example, using immiscible electrolyte systems or laminar flow systems.

Typically, an electrode is positioned in each side of the electrochemical cell. The electrode positioned in the catholyte-side of the cell may be termed the positive electrode and the electrode positioned in the anolyte side of the cell may be termed the negative electrode. Redox reactions take place at the interface between the catholyte and the positive electrode, and between the anolyte and the negative electrode. In a flow battery, the electrode do not take part in the redox reactions, but provide an active surface for the redox reactions to take place.

Preferably, the electrodes have high electrical conductivity, high specific surface area and good stability in the operating potential range of the flow battery. Preferably, the electrodes have good wettability and good resistance to corrosion by the electrolytes.

Typical electrolyte species include carbon-based materials. Examples of carbon-based electrodes include carbon-felt, carbon-paper and graphite-felt. The positive and negative electrodes materials may be the same or they may be different.

The electrochemical cell may comprise a current collector to collect electrical charge generated in the electrochemical cell. Typically, one current collector is positioned on the catholyte size of the electrochemical cell (the positive current collector) and is electrically connected to the positive electrode, and one current collector (the negative current collector) is positioned on the anolyte side of the electrochemical cell and is electrically connected to the negative electrode. The current collectors may be electrically connected to an external circuit.

Typical current collector materials include metals such as aluminium, steel and copper.

In an alternative embodiment, an active species may be deposited as a solid layer on or with one electrode during use (a hybrid flow battery). In such cases, a liquid electrolyte flows across the surface of the solid electrode in an electrochemical cell. Redox reactions take place at the interface between the liquid electrolyte and the surface of the electrode, storing or releasing charge. The liquid electrolyte may be either the catholyte or anolyte, and the solid electrode may be either cathode or anode as appropriate.

Typically hybrid flow batteries include zinc-plating batteries such as the zinc-bromine battery or zinc-cerium battery.

The flow battery may comprise multiple electrochemical cells, typically arranged in parallel.

A flow battery of the invention may be provided in a power grid management system. For example, a power grid management system for providing continuous power supply from a power generator, especially from intermittent power generation such as wind, tidal or solar power.

In one aspect, the invention provides a power grid management system comprising a flow battery of the invention.

A flow battery of the invention may be provided in an emergency (back-up) power system. For example, an emergency power system for providing continuous power supply for critical infrastructure, such as hospitals, data centres and other telecommunications equipment.

In one aspect, the invention provides an emergency power system comprising a flow battery of the invention.

A battery of the invention may be used in an electric vehicle. As the energy density of a flow battery is at present lower than for batteries which store charge in the solid state, the flow battery may be used in vehicles where energy density is less critical, such as such as a ship. However, as it is possible to replace discharged electrolyte with charged electrolyte, the flow battery of the invention may also be used in situations where an electric vehicle needs to take on energy quickly, and may be used in road or rail vehicles.

### Method

The present invention also provides a method for determining the state of charge of an electrolyte, and of a flow battery comprising an electrolyte. Preferably, the method uses the measurement device described above.

In one embodiment, the method comprises (a) flowing an electrolyte through a measurement region; (b) measuring the magnetic susceptibility of the electrolyte in the measurement region; and (c) determining the state of charge of the electrolyte based on the magnetic susceptibility of the electrolyte.

The method may comprise, as a first step, providing a detector configured to measure the magnetic susceptibility of the electrolyte in the measurement region. Suitable detectors are set out above. Preferably, the detector is a magnetic susceptibility balance

Typically, the method comprises flowing the electrolyte through a measurement device, such as through a flow tube with the measurement device. The method may comprise providing a measurement device. Suitable measurement devices and flow tubes are set about above, along with suitable pumps for encouraging flow of the electrolyte.

Preferably, the method comprises directly measuring the magnetic susceptibility of the electrolyte in the measurement region.

Preferably, the method comprises continuously determining the SOC of the electrolyte, or of the flow battery as a whole. In such cases, each of steps (a) to (c) is carried out continuously. Preferably, the method comprises determining the SOC of the flow battery in real-time. In such cases, each of steps (a) to (c) is carried out in real time.

As noted above, it is possible to determine the SOC of a flow battery by determining the SOC of an electrolyte within a flow battery. Accordingly, there is provided a method for determining the state of charge of a flow battery comprising (a) determining the state of charge of an electrolyte within the flow battery according an embodiment of the invention; and (b) determining the state of charge of the flow battery based on the state of charge of the electrolyte.

In such cases, the method may comprise providing a flow battery, such as a flow battery comprising an electrolyte. Suitable flow batteries and their components are set out above.

Preferably, the method comprises continuously determining the SOC of the flow battery. In such cases, steps (a) and (b) are carried out continuously. Preferably, the method comprises determining the SOC of the flow battery in real-time. In such cases, steps (a) and (b) are carried out in real time.

As noted above, the electrolytes typically used in flow systems contain radical species which are paramagnetic. As such, the electrolyte has a bulk magnetic susceptibility which can be measured. The correlation between the SOC of the electrolyte and the magnetic susceptibility of the electrolyte may be known. Accordingly, the method may comprise comparing the magnetic susceptibility of the electrolyte with the predetermined (known) correlation.

The correlation between the SOC of the electrolyte and the magnetic susceptibility of the electrolyte may be determined. The present invention provides a method for determining the correlation between the SOC of an electrolyte and the magnetic susceptibility of the electrolyte, the method comprising:
(a) providing a plurality of reference samples of the electrolyte, each reference sample comprising a known quantity of redox-active species, where the known quantities differ;
(b) measuring the magnetic susceptibility of each of the plurality of reference samples; and
(c) determining the correlation between the magnetic susceptibility of the electrolyte and SOC of the electrolyte.

A magnetic susceptibility balance may be used to measure the magnetic susceptibility of each of the plurality of reference samples.

Typically, the redox-active species include reduced and oxidised forms, as noted above. Optionally, the redox-active species may include one or more intermediate forms.

In some embodiments, the method further comprises determine the correlation between the SOC of the flow battery and the SOC of the electrolyte.

In some embodiments, the correlation between the magnetic susceptibility of the electrolyte and the SOC of the electrolyte is a linear correlation. Accordingly, the method may comprise fitting the magnetic susceptibility of the plurality of reference samples to a linear graph. The linear correlation may be positive or negative.

In some embodiments, the inventors have shown that the relationship between the magnetic suitability of the electrolyte and the (remaining) capacity of the battery may be given by the equation:

$$\\ \begin{matrix}Δ χ = \frac{{μ}_{eff}^{{}^{} 2} {μ}_{B}^{{}^{} 2}}{3 {k}_{B} {Tq}_{e} V} Q & ( 6 )\end{matrix}$$

where Δχ is the bulk magnetic susceptibility of the electrolyte, μ_{eff} is the effective magnetic moment in units of Bohr magnetons, μ_{B} is the Bohr magneton, k_{B} is the Boltzmann constant, T is temperature in Kelvin, qₑ is the charge of an electron (1.602×10⁻¹⁹ C), V is the volume of the electrolyte and where Q is the capacity of the battery. Thus, Δχ is linearly proportional to Q.

The SOC of the battery may be determined by comparing the (remaining) capacity of the battery to the maximum capacity. The maximum capacity of the battery may be known, or it may be measured using standard techniques.

As noted above, the magnetic susceptibility of a substance may be determined by measuring the force exerted by the sample on a nearby magnet. Accordingly, in some embodiments, the method may comprise, as a first step, (a) providing a first pair of magnets configured to establish a magnetic field across a measurement region. The magnetic susceptibility of the electrolyte may then be determined by measuring the force exerted on the magnets.

The correlation between the force exerted on the first pair of magnets, the magnetic susceptibility of the electrolyte and the SOC of the electrolyte may be known. Accordingly, the method may comprise comparing the force exerted on the first pair of magnets with the predetermined (known) correlation.

Alternatively, the correlation between the force exerted on the first pair of magnets, the magnetic susceptibility of the electrolyte and the SOC of the electrolyte may be determined. This may be done by (a) providing a suitable measurement device according to an embodiment of the invention; (b) providing a plurality of reference sample of the electrolyte, each reference sample comprising a known quantity of redox-active species, when the known quantities differ; (c) measuring the force exerted on the first pair of magnets by each of the plurality of reference samples; and (d) determining the correlation between the force exerted on the first pair of magnets and SOC of the electrolyte.

In some embodiments, the correlation between the force exerted on the first pair of magnets and the SOC of the electrolyte is a linear correlation. Accordingly, the method may comprise fitting the force exerted on the first pair of magnets by the plurality of reference samples to a linear graph.

In one embodiment, the first pair of magnets may be mechanically coupled to a second pair of magnets that are positioned to interact with a compensating magnetic field generated by a compensating electromagnet. In such cases, the force exerted on the first pair of magnets may be counterbalanced by varying (e.g. increasing) the supply of current to the compensating electromagnet. Accordingly, the method may comprise determining the SOC of the electrolyte, and optionally the magnetic susceptibility of the electrolyte, based on the current supplied to the compensating electromagnet. In some embodiments, the method may comprise determining the supply of current to the compensating electromagnet required to counterbalance the force exerted on the first pair of magnets (when the electrolyte is present in the measurement region).

The correlation between the current required to counterbalance the force exerted on the first pair of magnets, the magnetic susceptibility of the electrolyte and the SOC of the electrolyte may be known. Accordingly, the method may comprise comparing the current required to counterbalance the force exerted on the first pair of magnets with the predetermined (known) correlation.

Alternatively, the correlation between the SOC of the electrolyte, and optionally the magnetic susceptibility of the electrolyte, may be determined. This may be done by (a) providing a suitable measurement device according to an embodiment of the invention; (b) providing a plurality of reference sample of the electrolyte, each reference sample comprising a known quantity of redox-active species, when the known quantities differ; (c) measuring the current required to counterbalance the force exerted on the first pair of magnets for each of the plurality of reference samples; and (d) determining the correlation between the current required to counterbalance the force exerted on the first pair of magnets and SOC of the electrolyte.

As the force produced by the counterbalancing electromagnet is proportional to the current supplied to the electromagnet, the correlation between the current required to counterbalance the force exerted on the first pair of magnets and the SOC of the electrolyte, and optionally the magnetic susceptibility of the electrolyte, is a linear correlation. Accordingly, the method may comprise fitting the force exerted on the first pair of magnets by the plurality of reference samples to a linear graph.

As noted above, the magnetic susceptibility of a substance may be determined by measuring the force exerted on the sample by a nearby magnet. Accordingly, in some embodiments, the method may comprise, as a first and second step, (a) providing a first pair of magnets configured to establish a magnetic field across a measurement region and (b) providing a flow tube configured to permit an electrolyte to pass through the measurement region. The magnetic susceptibility of the electrolyte may then be determined by measuring the force exerted on the flow tube.

The correlation between the force exerted on the flow tube, the magnetic susceptibility of the electrolyte and the SOC of the electrolyte may be known. Accordingly, the method may comprise comparing the force exerted on the flow tube with the predetermined (known) correlation.

Alternatively, the correlation between the force exerted on the flow tube, the magnetic susceptibility of the electrolyte and the SOC of the electrolyte may be determined. This may be done by (a) providing a suitable measurement device according to an embodiment of the invention; (b) providing a plurality of reference sample of the electrolyte, each reference sample comprising a known quantity of redox-active species, when the known quantities differ; (c) measuring the force exerted on the flow tube when each of the plurality of reference samples is present in the measurement region; and (d) determining the correlation between the force exerted on the flow tube and SOC of the electrolyte.

In some embodiments, the correlation between the force exerted on the flow tube and the SOC of the electrolyte is a linear correlation. Accordingly, the method may comprise fitting the force exerted on the first pair of magnets by the plurality of reference samples to a linear graph.

### Rebalancing

When a flow battery is cycled, the concentration of redox-active species in the electrolytes (e.g. catholyte and anolyte) may become unbalanced. This may occur, for example, due to consumption of redox-active species by parasitic side-reactions, or by alternative (unproductive) redox processes occurring within the cell. This results in capacity loss in the battery system.

Accordingly, the invention also provides a method for rebalancing a flow battery, the method comprising:
(a) determining the state of charge of an electrolyte within a flow battery based on the magnetic susceptibility of the electrolyte according to an embodiment of the invention;
(b) determining the quantity redox-active species within the electrolyte based on the state of charge of the electrolyte;
(c) comparing the quantity of redox-active species within the electrolyte to a predetermined reference; and
(d) adjusting the concentration of redox-active species in the electrolyte.

As noted above, the redox-active species may have a reduced form, an oxidised form, and optionally one or more intermediate forms. Accordingly, the method may comprise determining the quantity of at least one of the reduced form, the oxidised form and optionally the one or more intermediate forms within the electrolyte based on the SOC of the electrolyte.

The concentration of redox-active species, or of each form of the redox-active species, in the electrolyte may be adjusted by introducing an additional quantity of one or more species into the electrolyte. Alternatively, the concentration of redox-active species may be adjusted by chemically or electrochemically reducing or oxidising a portion of the electrolyte as appropriate. For example, a secondary rebalancing cell may be provided and a portion of the electrolyte may be passed through the rebalancing cell and oxidised or reduced as appropriate.

### Cross-Over and Degradation

When a flow battery is cycled, additional by-products may arise in the electrolyte. For example, due to movement of the electrolyte across the across the membrane or separator in the electrochemical cell (“cross-over”), consumption of the electrolyte by parasitic side-reactions, or degradation of battery components such as the electrode surface. The additional by-products may be inert, but they may also be deleterious and result in capacity loss or shorten the lifetime of the flow battery.

The presence of by-products may alter the bulk magnetic susceptibility of the electrolyte. This situation occurs, for example, in a zinc-cerium system (Zn/Ce RBF), where paramagnetic Ce³⁺ ions that cross-over from the cerium-based catholyte to the zinc-based anolyte side could be easily detected over the diamagnetic Zn²⁺/Zn(0) species. In the worked examples show below, the paramagnetic Fe³⁺ species could also be detected when the cross-over from the iron-based catholyte to the anthraquinone-based anolyte.

Thus, comparing the bulk magnetic susceptibility of the electrolyte to a predetermined reference, for example to the expected magnetic susceptibility based on the state-of-charge of the electrolyte, allows such by-products to be detected.

Accordingly, the invention also provides a method for detecting cross-over or degradation occurring within a flow battery, the method comprising:
(a) flowing an electrolyte through a measurement region;
(b) measuring the magnetic susceptibility of the electrolyte in the measurement region;
(c) comparing the magnetic susceptibility of the electrolyte to a pre-determined reference; and
(c) determining the presence of by-product species within the electrolyte.

Thus, the method provides a rapid and simple method for detecting the presence of by-products within the electrolyte.

### Uses

The invention also provides use of the measurement devices described herein to determine the state of charge of a flow battery.

Accordingly, the invention provides use of a measurement device to determine the state of charge of a flow battery, the device comprising:
(a) a measurement region;
(b) a flow tube configured to permit an electrolyte to pass through the measurement region; and
(c) a detector configured to measure the bulk magnetic susceptibility of the electrolyte in the measurement region.

Preferred elements of the measurement device and methods set out above also apply to the use.

### Quantification of Dissolved Radical Species

The method for determining SOC outlined above are based on the principle that bulk magnetic susceptibility can be used to determine the quantity of a redox-active species present in the electrolyte. However, the ability to use magnetic susceptibility to detect the presence of a radical species may be useful in systems other than flow batteries.

Accordingly, the present invention also provides a method for detecting the presence of a radical species within an electrolyte, the method comprising:
(a) flowing the electrolyte through a measurement region;
(b) measuring the magnetic susceptibility of the electrolyte in the measurement region; and
(c) detecting the presence of a radical species within the electrolyte.

The radical species may be derived from polysulfide dissolution, metal dissolution, a redox mediator or a superoxide.

The relationship between the magnetic susceptibility of the electrolyte and the quantity of radical species may be known. Accordingly, the method may comprise quantifying (determining the amount of) the radical and/or paramagnetic species within the electrolyte.

This method may find use in systems such as lithium-sulfur batteries (detection of polysulfide dissolution) or lithium-air batteries (superoxide detection).

### Definitions

The term “coupled” as used herein may refers to two units that may be mechanically joined, two units that are in fluid communication (such that fluid may pass from one unit to the other), or two units that are electrically connected (such that current may flow from one unit to the other) as indicated by the context in which it is used.

Magnetic susceptibility, Δχ, is a measure of the extent to which a material may be magnetized in relation to an applied magnetic field. Volume susceptibility (χ) is the ratio of the magnetization M within the material (magnetic moment per unit volume) to the magnetic field strength H of the applied magnetic field. It is a dimensionless quantity.

Mass susceptibility (χₘ, units kg⁻¹m³) and molar susceptibility (χₘₒₗ, units mol⁻¹m³) may also be used, depending on context.

### Other Preferences

Each and every compatible combination of the embodiments described above is explicitly disclosed herein, as if each and every combination was individually and explicitly recited.

Various further aspects and embodiments of the present invention will be apparent to those skilled in the art in view of the present disclosure.

“and/or” where used herein is to be taken as specific disclosure of each of the two specified features or components with or without the other. For example, “A and/or B” is to be taken as specific disclosure of each of (i) A, (ii) B and (iii) A and B, just as if each is set out individually herein.

Unless context dictates otherwise, the descriptions and definitions of the features set out above are not limited to any particular aspect or embodiment of the invention and apply equally to all aspects and embodiments which are described.

### EXPERIMENTAL

Certain aspects and embodiments of the invention will now be illustrated by way of example and with reference to the figures described above.

In a first example, which is a comparative example, the bulk magnetic susceptibility is measured using an NMR technique. In a second example, which uses a method according to an embodiment of the invention, the bulk magnetic susceptibility is measured using a magnetic susceptibility balance.

### Example 1 (NMR Measurement)

The setup consists of a flow battery (Scribner), two peristaltic pumps (MasterFlex L/S 07751-20, Cole-Parmer), an electrochemical cycler (SP-150, BioLogic SAS), and an NMR (300 MHz, Bruker) spectrometer. The NMR sampling tube is shown in FIG. 1 and details are provided in Zhao et al. In the battery, 20 cm³ of 200 mM K₄[Fe(CN)₆] was used as the catholyte and 20 cm³ of 300 mM 2,6-dihydroxyanthraquinone (AQ) was used as the anolyte. The solvent was D₂O with 1 M KOH as the supporting electrolyte for the catholyte, and 1.6 M KOH for the anolyte. The battery compromises of two graphite flow plates with serpentine flow patterns, two 4.6 mm carbon felt electrodes (SGL) with a 5 cm² active area and a Nafion 212 membrane. The Nafion 212 membranes was treated by first heating the membrane in 80° C. deionized water for 20 min and then soaking it in 5% hydrogen peroxide solution for 35 min. The treated membranes were stored in 0.1 M KOH solution at room temperature for at least 24 hours before usage. The flow rate of the electrolytes was set at 13.6 cm³/min. Pseudo-2D NMR experiments were performed by direct excitation with a 90° radio-frequency pulse. Each NMR spectrum is acquired by collecting 8 free induction decays with a recycle delay of 5 s. The pulse width for a 90° pulse was 27 μs. All spectra were referenced to the water chemical shift at 4.79 ppm before battery cycling starts.

The shift of water resonance Δ δ in parts per million, is caused by the change of bulk magnetic susceptibility of the electrolyte, Δχ, following the relationship (Evans et al.):

$$\\ \begin{matrix}Δ δ = \frac{4}{3} π Δ χ & ( 1 )\end{matrix}$$

Here, Δχ is related to the change of concentration of the paramagnetic species, ΔC_{P}, by

$$\\ \begin{matrix}Δ χ = \frac{{N}_{A} {μ}_{eff}^{{}^{} 2} {μ}_{B}^{{}^{} 2}}{3 {k}_{B} T} Δ {C}_{P} & ( 2 )\end{matrix}$$

where N_{A} is Avogadro's constant, k_{B} is the Boltzmann constant, T is temperature in Kelvin, μ_{B} is the Bohr magneton, and μ_{eff} is the effective magnetic moment in units of Bohr magnetons. Assuming the spin-only formula, valid when the contributions to the orbital angular momentum can be ignored (and spin-orbit coupling is quenched or inherently zero), μ_{eff} is a direct measure of the number of unpaired electrons, n:

μ_{eff}=\sqrt{n(n+2)} (3)

where n can also be written in terms of S the total spin of the system (S=n/2). Combining Eq. 1 and 2, we obtain,

$$\\ \begin{matrix}Δ {C}_{P} = \frac{9 {k}_{B} T}{4 π {N}_{A} {μ}_{eff}^{{}^{} 2} {μ}_{B}^{{}^{} 2}} Δ δ & ( 4 )\end{matrix}$$

where ΔC_{P} is linearly related to Δ δ.

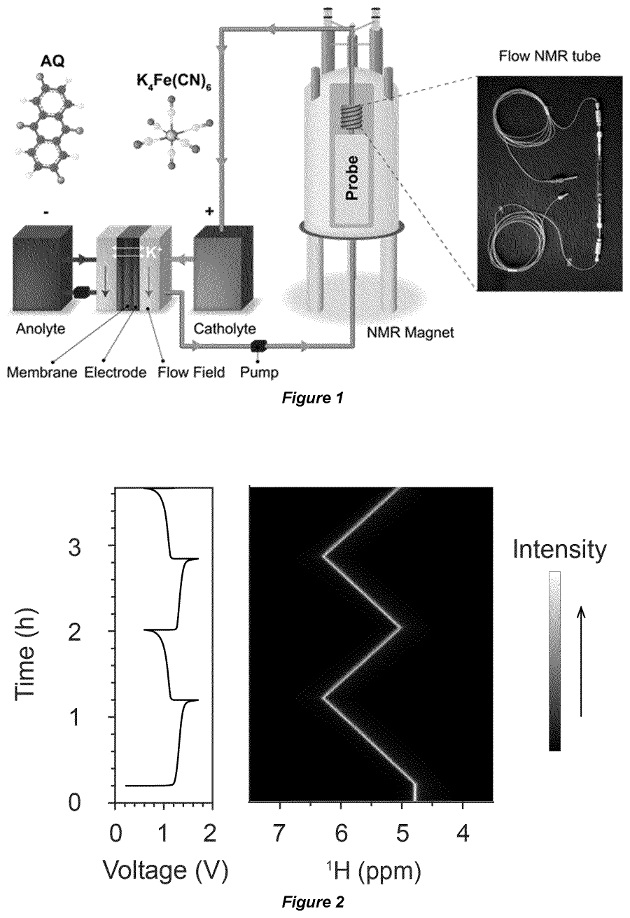

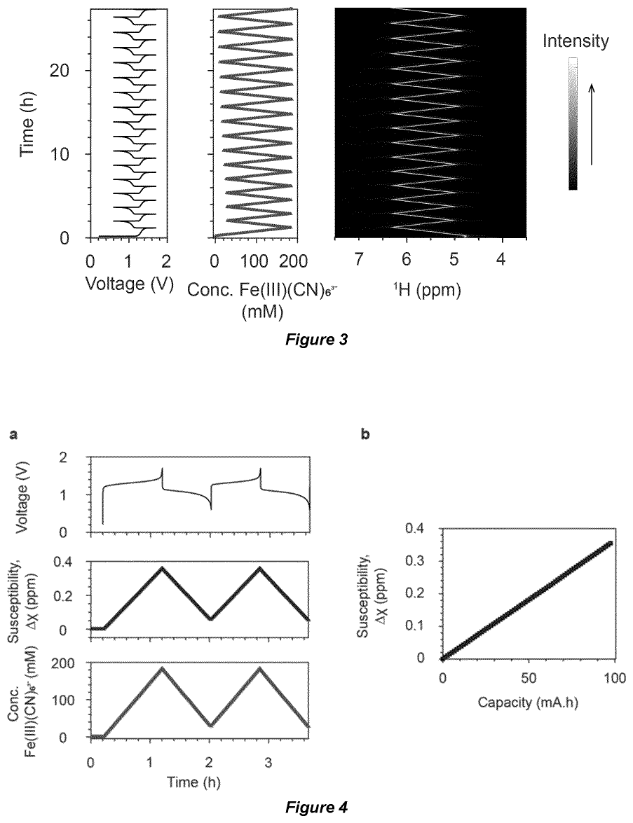

The in situ ¹H NMR spectra of the catholyte during electrochemical cycling is presented in FIG. 2. The acquisition of the ¹H NMR spectra started 13 minutes before the commencement of electrochemical cycling. During the in situ measurement, the battery was charged (oxidation of [Fe(II)(CN)₆]⁴⁻ to [Fe(III)(CN)₆]³⁻) at 100 mA to a cut-off voltage of 1.7 V, followed by a discharge (reduction of [Fe(III)(CN)₆]³⁻ to [Fe(II)(CN)₆]⁴⁻) at 100 mA to a cut-off voltage of 0.6 V. The only ¹H NMR observables in the catholyte solution are the residual protons in the deuterated solvent, existing in the form of H₂O or HDO. Their resonances are set at 4.79 ppm prior to electrochemical cycling, which is the chemical shift of pristine water at room temperature. Due to the diamagnetic property of [Fe(II)(CN)₆]⁴⁻ anions, the water resonances may deviate from 4.79 ppm. Nonetheless, since only the shifts of water resonances are used for analyses, these deviations are cancelled out. Upon charging, the resonance of H₂O shifts towards higher chemical shift to 6.28 ppm in a linear fashion. Upon discharging, the resonance of H₂O shifts back towards lower chemical shift to 5.02 ppm. In the following charge/discharge cycles, the spectra show a reversible trend (FIG. 2 and FIG. 3).

The changes of H₂O resonances are caused by the changes of bulk magnetization of the electrolyte solution. [Fe(II)(CN)₆]⁴⁻ anions are diamagnetic. [Fe(III)(CN)₆]³⁻ anions are paramagnetic where Fe³⁺ is in low-spin state, i.e. only a single unpaired electron in the t_{2g} orbital. The concentrations of [Fe(II)(CN)₆]⁴⁻ and [Fe(III)(CN)₆]³⁻ anions determine the bulk magnetization of the electrolyte solution. Based on the results from the in situ NMR measurement, the bulk magnetic susceptibility was calculated using Equation 1. FIG. 4a presents the voltage profile and the calculated bulk magnetic susceptibility of the catholyte solution as a function of time. During the first charge cycle, corresponding to the oxidation of [Fe(II)(CN)₆]⁴⁻ to [Fe(III)(CN)₆]³⁻ anions, Δχ increases linearly from 0 to 0.36 ppm. In the following discharge cycle, it decreases to 0.06 ppm linearly. In the subsequent charge/discharge cycles, reversible changes of Δχ were obtained.

FIG. 4b presents the plot of Δχ as a function of battery capacity Q. Δχ increases linearly to 0.36 ppm as the capacity reaches 97.4 mA.hr (theoretical capacity is 107.2 mA.hr). Fitting this data by Equation 6 gives a slope of 0.0036 ppm mA⁻¹hr⁻¹ with a coefficient of determinant R²=1.00. The effective magnetic moment μ_{eff} was calculated to be 2.14, which is higher than the spin-only value 1.73 due to the non-zero orbital contribution to the magnetic moment of the [Fe(III)(CN)₆]³⁻ anion, which is expected as only the t_{2g} orbitals are filled. A μ_{eff} value of 2.14 is close to 2.25 measured on potassium ferricyanide powders at 300 K (Figgis et al.).

Then, replacing μ_{eff} by 2.14 in Eq. 4, including the other constants, we obtain,

ΔC_{P}=122.18Δ δ (7)

where the concentration of ferricyanide can be calculated from the change in chemical shift (in ppm) using the factor of 122.18 mol/m³. The bottom panel of FIG. 2a presents the concentration of [Fe(III)(CN)₆]³⁻ anions as a function of time, calculated by using Equation 7. During the first charge cycle, the concentration of [Fe(III)(CN)₆]³⁻ anions increases linearly to 184.1 mM, then decreases to 29.0 mM in the following discharge cycle. During the second charge cycle, it increases to 183.8 mM and then decreases to 28.1 mM in the following discharge cycle. Reversible changes of concentrations as a function of electrochemical cycling were observed in the subsequent charge-discharge cycles (FIG. 3).

### Example 2 (Evans Balance Measurement)

The NMR results demonstrate that the bulk magnetization of electrolyte solution can be a useful indicator for the SOC of a flow battery and that NMR is a sensitive tool to measure this bulk magnetization. However, the high cost and bulky size of an NMR instrument make it impractical to be widely applied on commercial flow batteries. This motivated a search for a simpler and inexpensive technique to measure the bulk magnetization. The Evans balance, based on a torsion mechanism, is a good candidate. In this method, a paramagnetic sample introduced in a glass tube between the first pair of magnets causes a deflection that is compensated by an electromagnet between the balancing second pair of magnets, the required compensation measures the magnetic susceptibility.

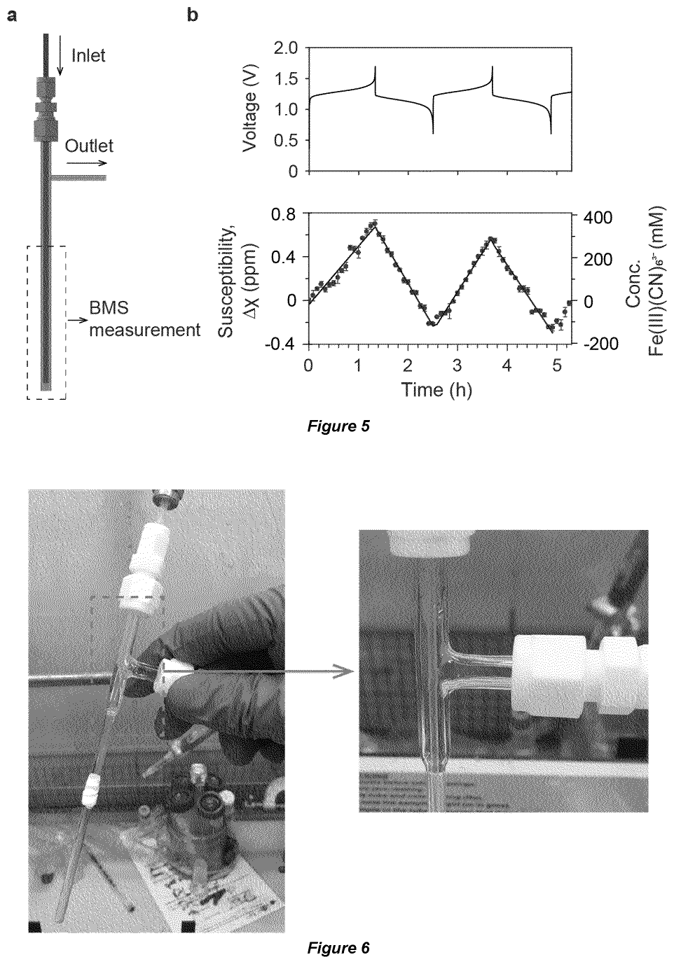

A flow tube was designed to fit into the cavity of an Evans balance. A tube-in-a-tube design was adopted as shown in FIG. 5a, in which a 1/16″ PFA tube is inserted into a 3 mm O.D. glass tube. The electrolyte solution flows to the bottom of the glass tube through the inner tube, and then flows out through the outer tube and the side arm attached to it. This design ensured smooth electrolyte flow through the reservoir, avoiding any stagnation points where stale electrolyte could accumulate.

To measure the magnetic susceptibility, an Evans balance (Johnson-Matthey, Mark I) was used, along with a modified a 3 mm NMR tube to allow a sampling tube to be placed in the balance at a depth of 50 mm (FIG. 6). The readings on the Evans balance were recorded by two cameras (the balance not providing any other digital output). The initial analysis reported here, measured the magnetic susceptibility every 5 minutes using five data points, each separated by 10 s. in the battery, 15 cm³ of 570 mM K₄[Fe(CN)₆] was used as the catholyte. 15 cm³ of 300 mM AQ was used as the anolyte. The solvent was D₂O with 1 M KOH as the supporting electrolyte for the catholyte, and 1.6 M KOH for the anolyte, respectively. The flow rate was set at 7.7 cm³/min. The battery was charged (oxidation of [Fe(II)(CN)₆]⁴⁻ to [Fe(III)(CN)₆]³⁻) at 150 mA to a cut-off voltage of 1.7 V, followed by a discharge (reduction of [Fe(III)(CN)₆]³⁻ to [Fe(II)(CN)₆]⁴⁻) at 150 mA to a cut-off voltage of 0.6 V.

As noted above, Δχ is related to the change of concentration of the paramagnetic species, ΔC_{P}, by

$$\\ \begin{matrix}Δ χ = \frac{{N}_{A} {μ}_{eff}^{{}^{} 2} {μ}_{B}^{{}^{} 2}}{3 {k}_{B} T} Δ {C}_{P} & ( 2 )\end{matrix}$$

where N_{A} is Avogadro's constant, kB is the Boltzmann constant, T is temperature in Kelvin, μB is the Bohr magneton, and μ_{eff} is the effective magnetic moment in units of Bohr magnetons.

ΔC_{P} can be calculated from the current during the electrochemical cycling, following

Q=N_{A}qₑVΔCₚ (5)

where Q is the (remaining) capacity of the battery in mA.h, qₑ is the charge of an electron (1.602×10⁻¹⁹C), V is the volume of the electrolyte.

Combining Eq. 2 and 5, we obtain,

$$\\ \begin{matrix}Δ χ = \frac{{μ}_{eff}^{{}^{} 2} {μ}_{B}^{{}^{} 2}}{3 {k}_{B} {Tq}_{e} V} Q & ( 6 )\end{matrix}$$

where Δχ is linearly proportional to Q.

The results obtained for the magnetic susceptibility are shown in FIG. 5b. The magnetic susceptibility exhibits linear growth when charging and a linear decline when discharging. Best fit lines to the two charge-discharge cycles demonstrate that the relationship is linear, despite the sensitivity of the readings to environmental factors. The linear change in magnetic susceptibility Δχ with time is strongly correlated with the linear change in capacity. Thus, to a first approximation, the change in the magnetic susceptibility appears to be directly proportional to the capacity and, therefore, the SOC of the battery. The Evans balance used in this study was not magnetically shielded and so is affected by changes in the local environment, which may explain some of the variations in the measurements shown in FIG. 4b. The sensitive apparatus could be disturbed through the movement of big magnetic objects nearby which causes the changes of the magnetic field; this was most notable, for example, through the opening of a cupboard door underneath the fume hood where the setup was located. For this reason, future experiments would benefit from an environment where movement of big magnetic objects are minimized. This requirement can be easily fulfilled for a commercial flow battery operating in the field.

### Example 3.a (Simple Balance Measurement)

An alternative means by which to measure magnetic susceptibility is by using fixed magnets placed directly on a weighing balance. This may be known as an Evans balance or a simple Evans balance. The balance is simpler and less expensive compared to a NMR instrument, making the technique more practical and commercially viable for redox flow batteries. The technique also has good sensitivity.

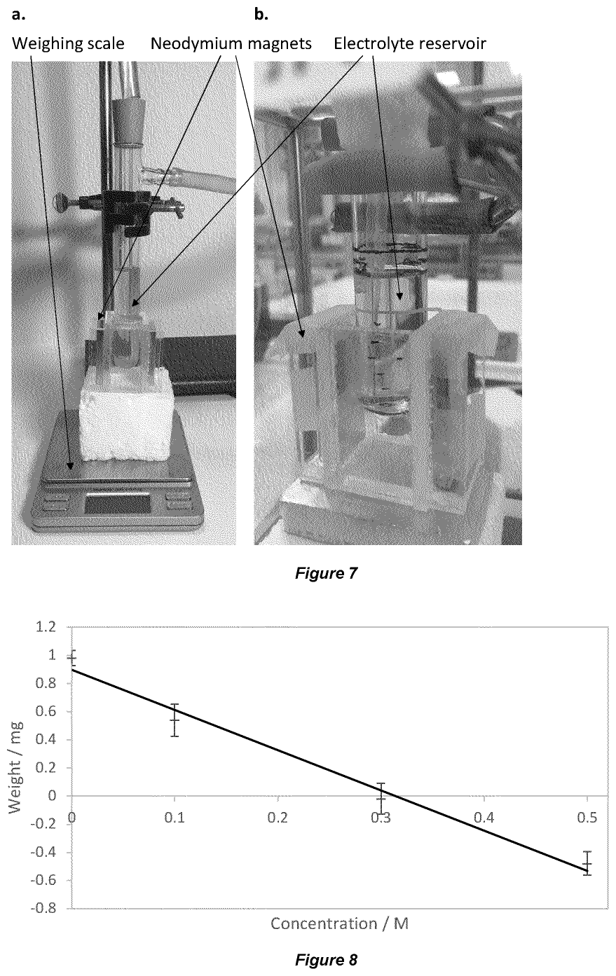

The example includes two fixed magnets on a weighing balance with an electrolyte reservoir suspended between the magnets, as shown in FIG. 7a and FIG. 7b. The magnets act on the weighing balance, while the electrolyte and electrolyte reservoir are suspended between the magnets (but do not act directly on the weighing balance). In the specific example shown in FIG. 7, the electrolyte reservoir is held between two fixed neodymium magnets on a sensitive laboratory balance (accurate to +/−0.1 mg). The weighing balance registers a change in the weight as a magnetically susceptible solution is flowed through. For a paramagnetic solution, the weighing balance registers a slight decrease in the weight measured by the weighing scale.

To measure the magnetic susceptibility, different concentrations of Fe(III) solution (K₃[Fe(III)(CN)₆]) were measured (from 0 to 0.5 M) using the balance shown in FIG. 7. The weight reading on the balance was measured for 0 M, 0.1 M, 0.3 M and 0.5 M of Fe(III) solution, as shown in the graph in FIG. 8. As the concentration of the solution increased, the weight on the balance decreased from about 1 mg to −0.6 mg, due to a change in the magnetic susceptibility of the electrolyte. Multiple readings were taken, and the mean and standard deviation were calculated (as shown by the error bars in FIG. 8).

The balance provided good calibration with this electrolyte reservoir, showing a clear change in weight and good resolution with changes in concentration of Fe(III) across a range which is typical for a cycling redox flow battery (i.e. from 0 to 0.5 M).

### Example 3.b (Counter Balance Measurement)

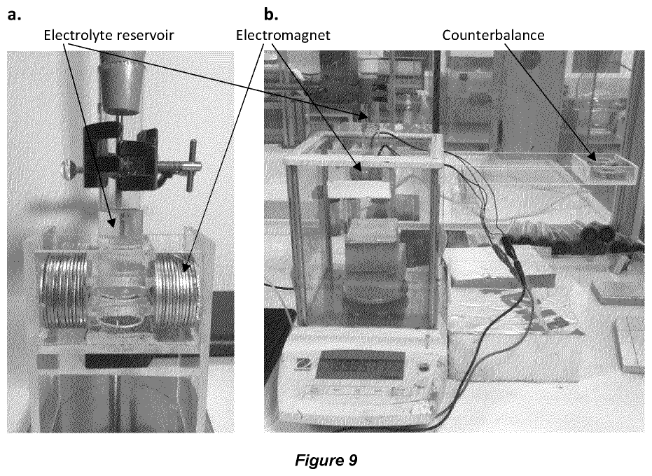

A second example balance was also tested. This includes two electromagnets with a counterbalanced acting on a weight balance, with an electrolyte reservoir held between the electromagnets, as shown in FIG. 9a and FIG. 9b. This may be known as an Evans balance. The electromagnets act on the weighing balance via a counterbalancing mechanism, while the electrolyte and electrolyte reservoir are suspended between the magnets (but do not act directly on the weighing balance). The additional weight of the electromagnets requires the counterbalanced configuration shown in FIG. 9b, to keep the overall weight on the balance below the weighing balance's maximum limit.

The electromagnets can be switched on briefly to take readings, and then switched off again. The readings are taken as the difference between the weight measured by the balance when the magnets are on and when they are off. The magnitude of the difference in the weight measured depends on the concentration of the magnetically susceptible solution (e.g. paramagnetic solution).

By only switching the electromagnets on briefly, the slow calibration drift in the measurements is less than when using fixed magnets. The reduction in slow calibration drift achieved by using electromagnets make the measurement more applicable for long term, in situ measurements of a redox flow battery.

The use of electromagnets is applicable to the system used in this example, but also to other Gouy-type balances or an Evans-type balances (e.g. as described in Example 2).

The balance described above can also be used with a flow tube as the electrolyte reservoir, as described for the Evans balance in Example 2.

Magnetic susceptibility can be measured using the weight readings of the balance, as described above for the Evans balance in Example 2.

### Comments

In this study, the bulk magnetization of the ferro/ferri cyanide electrolyte solution was measured as a function of electrochemical cycling. This was achieved by monitoring the shift of water resonances in the ¹H NMR spectra and using its linear relationship to the bulk magnetization of the electrolyte solution. Fitting the data of magnetic susceptibility as a function of battery capacity, we calculated the effective magnetic moments of the dissolved ferricyanide anions to be 2.14 μ_{B}. Further, the concentration of ferricyanide anions was calculated using this value, which allowed the SOC of the battery to be determined during cycling. Importantly, this method is applicable to a wide range of redox chemistries, where the magnetization of the electrolyte solution changes as a function of its oxidation state. This requirement is fulfilled by iron-, vanadium-, chromium-, manganese- and many organic molecule-based systems that involve radical anions.

Motivated by the NMR results, with the goal of developing a compact device that can be applied to large-scale flow batteries, an Evans balance was used to measure the bulk magnetization of the electrolytes. A linear correlation between the readings from the Evans balance and the capacity of the battery was obtained, closely corresponding with the NMR measurements of bulk magnetization. The Evans balance is an example of a simpler, smaller and cheaper device with sufficient sensitivity to measure variations in electrolyte magnetization. With a customized modification to the Evans balance or similar instrument, the design of a compact device that can be integrated into a commercial flow battery to reliably measure the state of charge is readily envisaged.

### REFERENCES

A number of publications are cited above in order to more fully describe and disclose the invention and the state of the art to which the invention pertains. Full citations for these references are provided below. The entirety of each of these references is incorporated herein.

WO 2008/100862 A1, Deeya Energy, Inc.

WO 2016/094436 A2, Lockheed Martin Advances Energy Storage, LLC.

Evans et al., “The determination of the paramagnetic susceptibility of substances in solution by nuclear magnetic resonance”, Journal of the Chemical Society (Resumed), 1959, pp. 2003-2005.

Figgis et al., “The crystallography and paramagnetic anisotropy of potassium ferricyanide”, Proceedings of the Royal Society of London. A. Mathematical and Physical Sciences, 1969, Vol. 309 (1496), pp. 91-118.

Skyllas-Kazacos et al., “Vanadium redox flow batteries (VRBs) for medium- and large-scale energy storage”, Chapter 10, in Advances in Batteries for Medium and Large-Scale Energy Storage, Eds Menictas, et al., Woodhead Publishing: 2015; pp 329-386.

Skyllas-Kazacos et al., “State of charge monitoring methods for vanadium redox flow battery control”, Journal of Power Sources, 2011, Vol. 196 (20), pp. 8822-8827.

Tong, et al., “UV-Vis spectrophotometry of quinone flow battery electrolyte for in situ monitoring and improved electrochemical modeling of potential and quinhydrone formation”, Physical Chemistry Chemical Physics, 2017, Vol. 19 (47), pp. 31684-31691.

Zhao et al., “In situ NMR metrology reveals reaction mechanisms in redox flow batteries”, Nature, 2020, Vol. 579, pp. 224-228.

WO 2010/091170, Magna-lastic Devices Inc.

EP 2535730, Methode Electronics Inc.

1. A method for determining the state of charge of an electrolyte, the method comprising:
(a) flowing the electrolyte through a measurement region;
(b) measuring the magnetic susceptibility of the electrolyte in the measurement region; and
(c) determining the state of charge of the electrolyte based on the magnetic susceptibility of the electrolyte.

2. The method of claim 1 comprising, as a first step:
(a) providing a detector configured to measure the magnetic susceptibility of the electrolyte in the measurement region,
wherein the detector is a magnetic susceptibility balance.

3. The method of claim 1, comprising, as a first step:
(a) providing a first pair of magnets configured to establish a magnetic field across a measurement region,
and wherein the magnetic susceptibility of the electrolyte is determined by measuring the force exerted on the magnets.

4. The method of claim 1, comprising, as a first and second step:
(a) providing a first pair of magnets configured to establish a magnetic field across a measurement region,
(b) providing a flow tube configured to permit an electrolyte to pass through the measurement region,
and wherein the magnetic susceptibility of the electrolyte is determined by measuring the force exerted on the flow tube.

5. The method of claim 1, wherein the state of charge of the electrolyte is determined continuously.

6. A measurement device for determining the state of charge of an electrolyte, the device comprising:
(a) a measurement region;
(b) a flow tube configured to permit the electrolyte to pass through the measurement region; and
(c) a detector configured to measure the magnetic susceptibility of the electrolyte in the measurement region,
wherein the detector is a magnetic susceptibility balance.

7. The device of claim 6, wherein the magnetic susceptibility balance is an Evans-type balance.

8. The device of claim 6, wherein the magnetic susceptibility balance comprises:
(a) a first pair of magnets configured to establish a first magnetic field across the measurement region; and
(b) a sensor configured to determine the force exerted on the first pair of magnets.

9. The device of claim 8, wherein the magnetic susceptibility balance further comprises a beam having first and second ends, and wherein:
(a) the first pair of magnets are positioned at the first end of the beam; and
(b) the sensor is configured to measure the force exerted on the beam.

10. The device of claim 9 comprising:
(a) a second pair of magnets positioned at the second end of the beam and configured to establish a second magnetic field; and
(b) a compensating electromagnet configured to generate a compensating magnetic field to interact with the second magnetic field,
wherein, the sensor is configured to measure the current supplied to the compensating electromagnet.

11. The device of claim 9, comprising a second sensor configured to determine whether the beam is in the rest position.

12. (canceled)

13. The device of claim 6, wherein the magnetic susceptibility balance is a Gouy-type balance.

14. The device of claim 6, wherein the magnetic susceptibility balance comprises:
(a) a first pair of magnets configured to establish a first magnetic field across the measurement region; and
(b) a sensor configured to determine the force exerted on the flow tube.

15. The device of claim 6, wherein the flow tube comprises:
(a) an outer tube, coupled to an outlet at a first end and sealed at a second end; and
(b) an inner tube positioned within the outer tube, the inner tube open at a second end and coupled to an inlet at a first end,
such that the electrolyte must pass from the inlet through the inner tube, into the outer tube and then through the outer tube to the outlet.

16. The device of claim 6, comprising a data processing unit configured to determine a state of charge of the electrolyte based on the magnetic susceptibility of the electrolyte, and
a data storage unit for storing the correlation between the magnetic susceptibility of the electrolyte and the state of charge of the electrolyte;
wherein:
(a) the data processing unit is configured to determine the state of charge of a flow battery comprising the electrolyte based on the state of charge of the electrolyte; and
(b) the data storage unit is configured to store the correlation between the state of charge of the flow battery and the state of charge of the electrolyte.

17-19. (canceled)

20. The device of claim 6, wherein the device is integrated into a flow battery or hybrid flow battery.

21. (canceled)

22. The method of claim 1, wherein the electrolyte is within a flow battery and the method is for determining the state of charge of a flow battery, the method further comprising:
(d) determining the state of charge of the flow battery based on the state of charge of the electrolyte.

23. The method of claim 1, wherein the electrolyte is within a flow battery and the method is for rebalancing a flow battery, the method further comprising:
(d) determining the quantity of redox-active species within the electrolyte based on the state of charge of the electrolyte;
(e) comparing the quantity of redox-active species within the electrolyte to a predetermined reference; and
(f) adjusting the concentration of redox-active species within the electrolyte.

24. The method of claim 23, wherein the concentration of redox-active species within the electrolyte is adjusted by at least one of (i) introducing an additional quantity of one or more redox-active species into the electrolyte, or (ii) chemically or electrochemically reducing or oxidising a portion of the electrolyte.

25. (canceled)

26. A method for detecting cross-over or degradation occurring within a flow battery, the method comprising:
(a) flowing an electrolyte through a measurement region;
(b) measuring the magnetic susceptibility of the electrolyte in the measurement region;
(c) comparing the magnetic susceptibility of the electrolyte to a predetermined reference; and
(d) determining the presence of by-product species within the electrolyte.
